(19) United States
(12) Patent Application Publication
(10) Pub. No.: US 2014/0166093 A1
(43) Pub. Date: Jun. 19, 2014

(54) SOLAR CELL EMITTER REGION FABRICATION USING N-TYPE DOPED SILICON NANO-PARTICLES

(71) Applicants: Paul Loscutoff, Castro Valley, CA (US); Peter J. Cousins, Menlo Park, CA (US); Steven Edward Molesa, San Jose, CA (US); Ann Waldhauer, La Honda, CA (US)

(72) Inventors: Paul Loscutoff, Castro Valley, CA (US); Peter J. Cousins, Menlo Park, CA (US); Steven Edward Molesa, San Jose, CA (US); Ann Waldhauer, La Honda, CA (US)

(21) Appl. No.: 13/718,503

(22) Filed: Dec. 18, 2012

(51) Int. Cl. H01L 31/0236; H01L 31/02

(52) U.S. Cl. CPC H01L 31/02363; H01L 31/02002; Y10S 977/773
USPC 136/256; 438/98; 438/71; 136/261

(57) ABSTRACT

Methods of fabricating solar cell emitter regions using N-type doped silicon nano-particles and the resulting solar cells are described. In an example, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. At least a portion of the P-type dopant-containing layer is mixed with at least a portion of each of the plurality of regions of N-type doped silicon nano-particles.

### TECHNICAL FIELD

Embodiments of the present invention are in the field of renewable energy and, in particular, methods of fabricating solar cell emitter regions using N-type doped silicon nano-particles and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present invention allow for increased solar cell manufacture efficiency by providing novel processes for fabricating solar cell structures. Some embodiments of the present invention allow for increased solar cell efficiency by providing novel solar cell structures.

### BRIEF DESCRIPTION OF THE DRAWINGS

FIGS. 1A-1E and 1E′ illustrate cross-sectional views of various stages in the fabrication of a solar cell, in accordance with an embodiment of the present invention.

FIGS. 2A-2G illustrate cross-sectional views of various stages in the fabrication of a solar cell, in accordance with another embodiment of the present invention.

### DETAILED DESCRIPTION

Methods of fabricating solar cell emitter regions using N-type doped silicon nano-particles and the resulting solar cells are described herein. In the following description, numerous specific details are set forth, such as specific process flow operations, in order to provide a thorough understanding of embodiments of the present invention. It will be apparent to one skilled in the art that embodiments of the present invention may be practiced without these specific details. In other instances, well-known fabrication techniques, such as lithography and patterning techniques, are not described in detail in order to not unnecessarily obscure embodiments of the present invention. Furthermore, it is to be understood that the various embodiments shown in the figures are illustrative representations and are not necessarily drawn to scale.

Disclosed herein are methods of fabricating solar cells. In one embodiment, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. At least a portion of the P-type dopant-containing layer is mixed with at least a portion of each of the plurality of regions of N-type doped silicon nano-particles. In another embodiment, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. An etch resistant layer is formed on the P-type dopant-containing layer. A second surface of the substrate, opposite the first surface, is etched to texturize the second surface of the substrate. The etch resistant layer protects the P-type dopant-containing layer during the etching.

Also disclosed herein are solar cells. In one embodiment, an emitter region of a solar cell includes a plurality of regions of N-type doped silicon nano-particles disposed on a first surface of a substrate of the solar cell. Corresponding N-type diffusion regions are disposed in the substrate. A P-type dopant-containing layer is disposed on the plurality of regions of N-type doped silicon nano-particles and on the first surface of the substrate between the regions of N-type doped silicon nano-particles. Corresponding P-type diffusion regions are disposed in the substrate, between the N-type diffusion regions. An etch resistant layer is disposed on the P-type dopant-containing layer. A first set of metal contacts is disposed through the etch resistant layer, the P-type dopant-containing layer and the plurality of regions of N-type doped silicon nano-particles, and to the N-type diffusion regions. A second set of metal contacts is disposed through the etch resistant layer and the P-type dopant-containing layer, and to the P-type diffusion regions.

In a first aspect, one or more specific embodiments are directed to approaches for printing n-type silicon (Si) nano-particles and subsequently depositing a B₂O₃ oxide layer using boron tribromide (BBr₃) as a precursor. The BBr₃ precursor can be used to convert the Si nano-particles into a borophosphosilicate glass (BPSG) layer for use as a phosphorous diffusion source. Additionally, B₂O₃ is deposited in non-printed regions for use as a boron diffusion source. The approach can be used reduce or eliminate patterning and dopant deposition operations for solar cells having emitter regions formed in a bulk substrate or above a bulk substrate.

More specifically, in such fabrication process schemes, a patterned dopant source can be used for efficient doping. To achieve a useful pattern, a blanket deposition is typically followed by mask and etch lithography steps. Instead, one or more embodiments described herein involves patterning of a dopant source directly during deposition. Earlier attempts at direct patterning have included inkjet dopant formation. Other alternatives have involved inkjet and screenprint dopants that are oxide based, rather than Si nano-particle based. The materials for the earlier approaches can prove difficult to develop. In yet another earlier attempt, Si nano-particles are printed and a borosilicate glass (BSG) layer is formed on the Si nano-particles by APCVD. However, in such an approach, the nano-particles do not form a dense cohesive layer, and minimal phosphorous is available for being driven into an underlying substrate.

More generally, in the first aspect, one or more embodiments are directed to approaches for forming doped layers or regions in or above a substrate. In the case of forming doped diffusion regions in a bulk crystalline substrate, the ultimately formed emitter regions can be formed in, e.g., a bulk single crystalline silicon substrate. In the case of forming doped layers above a substrate, the ultimately formed emitter regions can be formed in, e.g., a polycrystalline or silicon layer. In either case, n-type Si nano-particles are printed on a region to be doped. The printing can be performed by screen-printing, inkjet printing, extrusion printing or aerosol jet printing, or other like approaches. Subsequent to printing, the receiving substrate can be placed in a diffusion furnace. A BBr₃ deposition is performed to grow B₂O₃ on the wafer. The B₂O₃ layer fills in the voids in the Si nano-particle film, creating a densely networked layer. On the non-printed region, a typical B₂O₃ layer is deposited. After BBr₃ deposition, the wafers are annealed in a high temperature diffusion step, which drives boron into the substrate from the B₂O₃ regions. In the Si nano-particle-printed regions, the phosphorous-doped Si is consumed by the B₂O₃ to form a silicate glass. The silicate glass layer is doped with both a heavy concentration of phosphorous and a more dilute concentration of boron, due to the smaller volume of voids than nano-particles. The result is a boron and phosphorous doped silicate glass (BPSG) layer. The BPSG layers can be used to preferentially drive phosphorous into silicon. Accordingly, the diffusion step involves a dominant phosphorous diffusion into the substrate from the BPSG (printed) area (with possibly some boron as well), and a boron diffusion from the B₂O₃, non-printed, regions.

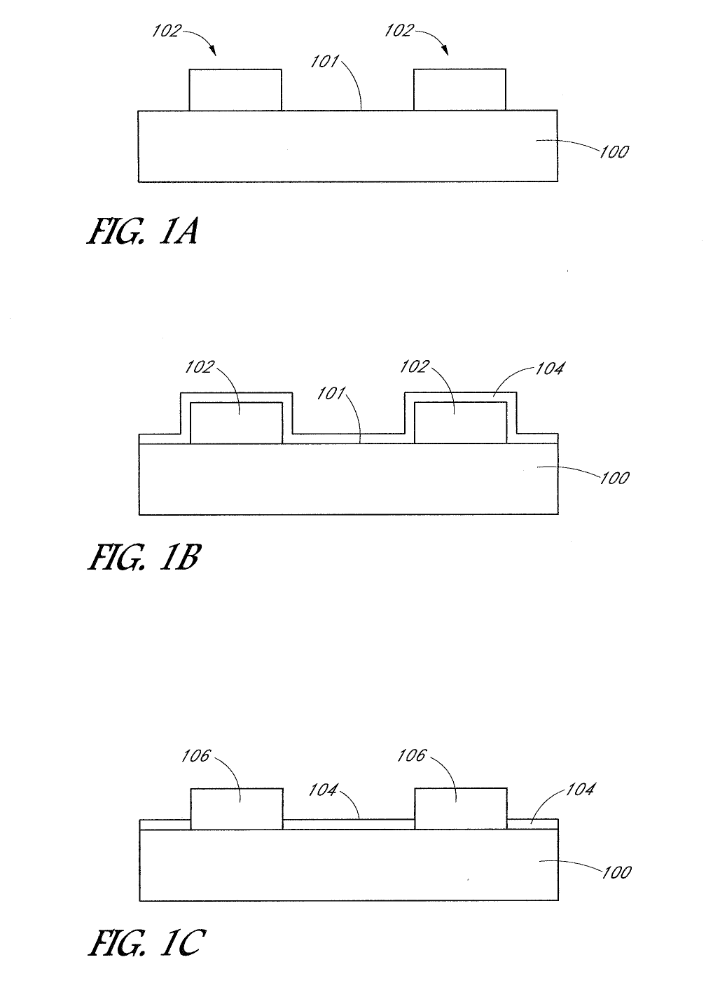

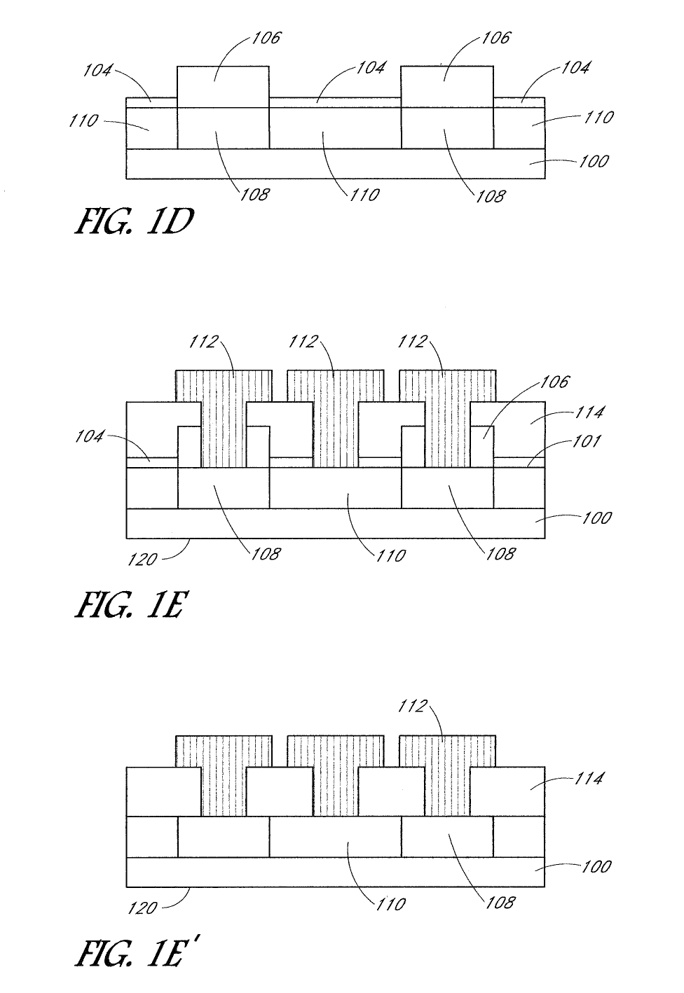

As an example, FIGS. 1A-1E and 1E′ illustrate cross-sectional views of various stages in the fabrication of a solar cell, in accordance with an embodiment of the present invention.

Referring to FIG. 1A, a method of fabricating emitter regions of a solar cell includes forming a plurality of regions of N-type doped silicon nano-particles 102 on a first surface 101 of a substrate 100 of the solar cell. In an embodiment, the substrate 100 is a bulk silicon substrate, such as a bulk single crystalline N-type doped silicon substrate. It is to be understood, however, that substrate 100 may be a layer, such as a polycrystalline silicon layer, disposed on a global solar cell substrate.

In an embodiment, the plurality of regions of N-type doped silicon nano-particles 102 is formed by printing or spin-on coating phosphorous-doped silicon nano-particles on the first surface 101 of a substrate 100. In one such embodiment, the phosphorous-doped silicon nano-particles have an average particles size approximately in the range of 5-100 nanometers and a porosity approximately in the range of 10-50%. In a specific such embodiment, the phosphorous-doped silicon nano-particles are delivered in the presence of a carrier solvent or fluid which can later evaporate or be burned off. In an embodiment, when using a screen print process, it may be preferable to use a liquid source with high viscosity for delivery since using a low viscosity liquid may lead to bleeding, and hence resolution reduction of defined regions.

Referring to FIG. 1B, the method also includes forming a P-type dopant-containing layer 104 on the plurality of regions of N-type doped silicon nano-particles 102 and on the first surface 101 of the substrate 100, between the regions of N-type doped silicon nano-particles 102.

In an embodiment, the P-type dopant-containing layer 104 is formed by depositing a layer of boron oxide (B₂O₃) on the plurality of regions of N-type doped silicon nano-particles 102 and on the first surface 101 of the substrate 100 between the regions of N-type doped silicon nano-particles 102. In one such embodiment, the layer of B₂O₃ is formed by reacting boron tribromide (BBr₃) and oxygen (O₂).

Referring to FIG. 1C, the method also includes mixing at least a portion of the P-type dopant-containing layer 104 with at least a portion of each of the plurality of regions of N-type doped silicon nano-particles 102.

In an embodiment, the mixing is performed by heating the substrate 100. In one such embodiment, the mixing is performed by heating at a temperature approximately in the range of 700-1100 degrees Celsius for a duration approximately in the range of 1-100 minutes. In an embodiment, the N-type doped silicon nano-particles 102 are phosphorus-doped silicon nano-particles, the P-type dopant-containing layer 104 is a boron-containing layer, and mixing the P-type dopant-containing layer 104 with the regions of N-type doped silicon nano-particles 102 involves forming corresponding regions of borophosphosilicate glass (BPSG) 106. In an embodiment, the mixing densifies the N-type doped silicon nano-particles 102 to provide a less porous or non-porous BPSG layer.

Referring to FIG. 1D, the method also includes, subsequent to mixing the P-type dopant-containing layer 104 with the regions of N-type doped silicon nano-particles 102, diffusing N-type dopants from the regions of N-type doped silicon nano-particles 106 to form corresponding N-type diffusion regions 108 in the substrate 100. Additionally, P-type dopants are diffused from the P-type dopant-containing layer 104 and forming corresponding P-type diffusion 110 regions in the substrate 100, between the N-type diffusion regions 108.

In an embodiment, the diffusing is performed by heating the substrate 100. In one such embodiment, the heating for diffusing is performed in a same process operation as heating to mix the P-type dopant-containing layer 104 with the regions of N-type doped silicon nano-particles 102. In an alternative such embodiment, however, the heating for diffusing is performed in a different process operation as heating to mix the P-type dopant-containing layer 104 with the regions of N-type doped silicon nano-particles 102. In an embodiment, as described briefly above, diffusing N-type dopants from the regions of N-type doped silicon nano-particles 106 further includes diffusing an amount of P-type dopants from the doped silicon nano-particles 106. As such, the corresponding N-type diffusion regions 108 ultimately include that amount of P-type dopants.

Referring to FIG. 1E, in an embodiment, the first surface 101 of the substrate 100 is a back surface of the solar cell, the second surface 120 of the substrate 100 is a light receiving surface of the solar cell, and the method also includes forming metal contacts 112 to the N-type and P-type diffusion regions 108 and 110. In one such embodiment, the contacts 112 are formed in openings of an insulator layer 114 and through remaining portions of the P-type dopant-containing layer 104 and the regions 106, as depicted in FIG. 1E. In another embodiment, however, referring to FIG. 1E′, remaining portions of the P-type dopant-containing layer 104 and the regions 106 are removed prior to formation of contacts 112 in openings of the insulator layer 114. In one specific such embodiment, the remaining portions of the P-type dopant-containing layer 104 and the regions 106 are removed with a dry etch process. In another specific such embodiment, the remaining portions of the P-type dopant-containing layer 104 and the regions 106 are removed with a wet etch process. In an embodiment, the dry or wet etch process is mechanically aided. In an embodiment, the conductive contacts 112 are composed of metal and are formed by a deposition, lithographic, and etch approach.

In a second aspect, one or more specific embodiments are directed to providing a bottom anti-reflective coating (bARC) deposition of silicon nitride (SiNx) before a random texturing (rantex) operation. In such an approach, the SiNx layer can be used as an etch-resist during the rantex etch. Generally, in developing a screen-printable dopant for bulk substrate solar cell fabrication, one technical issues involves having a dopant source material survive a rantex etch intact, so that it will be present for a subsequent dopant drive (e.g., P-drive) diffusion operation. Earlier attempts have included using a thick APCVD USG layer to prevent etching and moving the texture etch to a single-sided etching following a damaging etch. Other approaches for etch resistance in dopant sources have included reformulating the material to add etch resistance, densifying the film prior to APCVD deposition, and the use of single-sided rantex techniques. These approaches, however, take time to develop and some require new tools, rendering them non-ideal for retrofitting into existing fabs.

More specifically, one or more embodiments in the second aspect address a need for increasing rantex resistance for dopant film stacks. In a particular embodiment, a plasma-enhanced chemical vapor deposited (PECVD) SiNx is used since the layer has a low (undetectable) etch rate in, e.g., KOH. Furthermore, since PECVD SiNx can be used as a bARC layer in bulk substrate based solar cell, existing toolsets and architectures can be maintained while increasing the etch resistance of the film stack by moving the bARC deposition after atmospheric pressure chemical vapor deposition (APCVD) and before rantex. The resulting improved etch resistance may be particularly important for dopant material film stack that readily etches in KOH. Furthermore, the SiNx layer can provide an added advantage of defect fill-in for formed APCVD layers, where present defects are covered and sealed by the SiNx layer.

Although, for example, an undoped silicate glass (USG) layer formed by APCVD has a lower etch rate than Si, close to 2000 Angstroms of USG are typically etched in the rantex process. With SiNx on top of the film stack, the thickness (and therefore operating cost) of the USG layer can be reduced. The inclusion of an SiNx layer can add a degree of robustness to a standard film stack as well. Modifications of the current processing to allow for operation reduction can, in an embodiment, further include deposition of a doped layer (e.g., BSG or PSG) by PECVD instead of APCVD. Another option is to use doped SiNx:B or SiNx:P layers as dopant sources for diffusion. These layers can be formed to be thinner, due to the low etch rate of SiNx in KOH, while eliminating the APCVD tool in favor of using the PECVD bARC tool. In one such embodiment, a PECVD SiNx layer can be implemented along with other approaches to increase rantex resistance, such as dopant film densification.

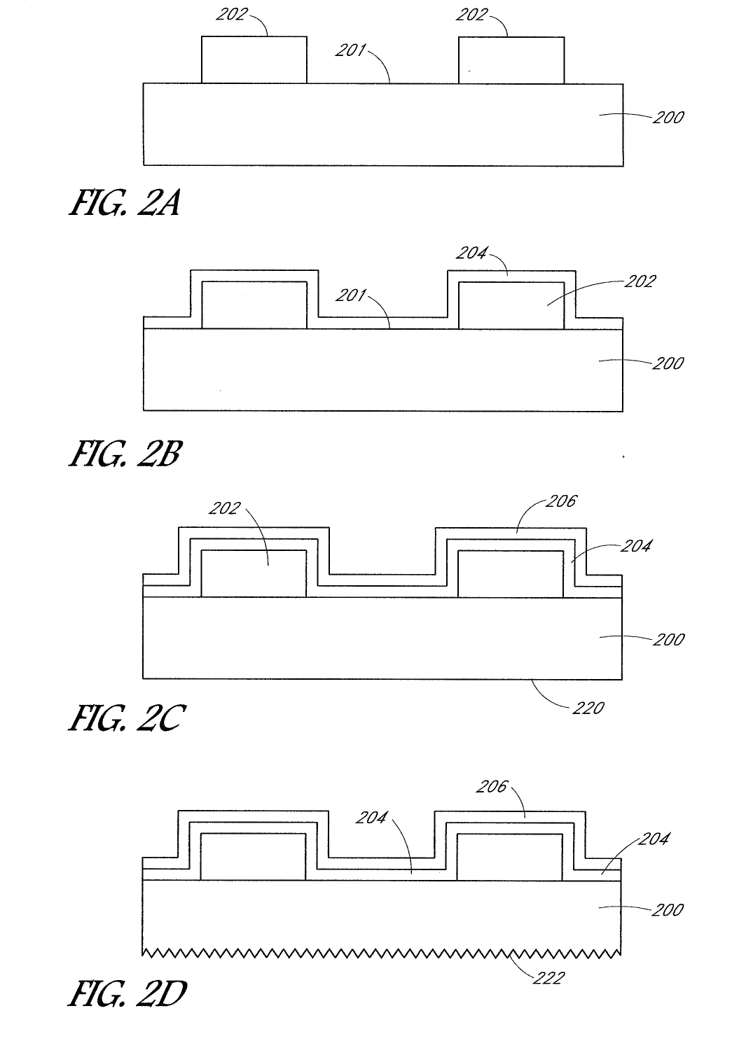

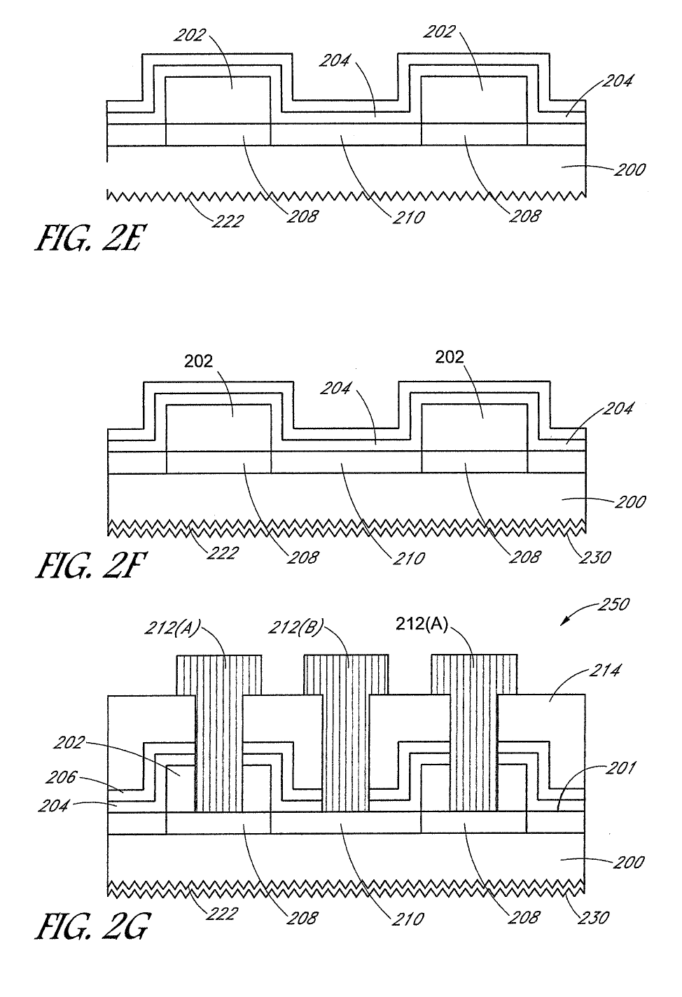

As an example, FIGS. 2A-2G illustrate cross-sectional views of various stages in the fabrication of a solar cell, in accordance with another embodiment of the present invention.

Referring to FIG. 2A, a method of fabricating emitter regions of a solar cell includes forming a plurality of regions of N-type doped silicon nano-particles 202 on a first surface 201 of a substrate 200 of the solar cell. In an embodiment, the substrate 200 is a bulk silicon substrate, such as a bulk single crystalline N-type doped silicon substrate. It is to be understood, however, that substrate 200 may be a layer, such as a polycrystalline silicon layer, disposed on a global solar cell substrate.

In an embodiment, the plurality of regions of N-type doped silicon nano-particles 202 is formed by printing or spin-on coating phosphorous-doped silicon nano-particles on the first surface 201 of a substrate 200. In one such embodiment, the phosphorous-doped silicon nano-particles have an average particles size approximately in the range of 5-100 nanometers and a porosity approximately in the range of 10-50%. In a specific such embodiment, the phosphorous-doped silicon nano-particles are delivered in the presence of a carrier solvent or fluid which can later evaporate or be burned off. In an embodiment, when using an ink jet process, it may be preferable to use a liquid source with low viscosity for porous layer since using a high viscosity liquid may lead to bleeding, and hence resolution reduction, or defined regions.

Referring to FIG. 2B, the method also includes forming a P-type dopant-containing layer 204 on the plurality of regions of N-type doped silicon nano-particles 202 and on the first surface 201 of the substrate 200 between the regions of N-type doped silicon nano-particles 202. In an embodiment, the P-type dopant-containing layer 204 is a layer of borosilicate glass (BSG).

Referring to FIG. 2C, the method also includes forming an etch resistant layer 206 on the P-type dopant-containing layer 204. In an embodiment, the etch resistant layer 206 is a silicon nitride layer.

Referring to FIG. 2D, the method also includes etching a second surface 220 of the substrate 200, opposite the first surface 201, to provide a texturized second surface 222 of the substrate 200. A texturized surface may be one which has a regular or an irregular shaped surface for scattering incoming light, decreasing the amount of light reflected off of the light-receiving surface of the solar cell. In one embodiment, the etching is performed by using a wet etch process such as an alkaline etch based on potassium hydroxide. In an embodiment, the etch resistant layer 206 protects the P-type dopant-containing layer 204 during the etching.

Referring to FIG. 2E, in an embodiment, the method also includes, subsequent to forming the P-type dopant-containing layer 204, heating the substrate 200 to diffuse N-type dopants from the regions of N-type doped silicon nano-particles 202 and form corresponding N-type diffusion regions 208 in the substrate 200. Additionally, P-type dopants are diffused from the P-type dopant-containing layer 204 to form corresponding P-type diffusion regions 210 in the substrate 200, between the N-type diffusion regions 208.

In an embodiment, the heating is performed at a temperature approximately in the range of 850-1100 degrees Celsius for a duration approximately in the range of 1-100 minutes. In one such embodiment, the heating is performed subsequent to the etching used to provide texturized second surface 222 of the substrate 200, as depicted in FIGS. 2D and 2E.

Referring to FIG. 2F, in an embodiment, the method also includes, subsequent to etching the second surface of the substrate 200, forming an anti-reflective coating layer 230 on the texturized second surface 222 of the substrate 200.

Referring to FIG. 2G, in an embodiment, the first surface 201 of the substrate 200 is a back surface of the solar cell, the texturized second surface 222 of the substrate 200 is a light receiving surface of the solar cell, and the method also includes forming metal contacts 212 to the N-type and P-type diffusion regions 208 and 210. In one such embodiment, the contacts 212 are formed in openings of an insulator layer 214 and through remaining portions of the N-type doped silicon nano-particles 202, the P-type dopant-containing layer 204, and the etch resistant layer 206, as depicted in FIG. 2G. In an embodiment, the conductive contacts 212 are composed of metal and are formed by a deposition, lithographic, and etch approach.

In another embodiment, not depicted, remaining portions of the N-type doped silicon nano-particles 202, the P-type dopant-containing layer 204, and the etch resistant layer 206 are removed prior to formation of contacts 212 in openings of the insulator layer 214. In one specific such embodiment, the remaining portions of the N-type doped silicon nano-particles 202, the P-type dopant-containing layer 204, and the etch resistant layer 206 are removed with a dry etch process. In another specific such embodiment, the remaining portions of the N-type doped silicon nano-particles 202, the P-type dopant-containing layer 204, and the etch resistant layer 206 are removed with a wet etch process. In an embodiment, the dry or wet etch process is mechanically aided.

Referring again to FIG. 2G, a fabricated solar cell 250 may this include an emitter region composed of a region of N-type doped silicon nano-particles 202 disposed on a first surface 201 of a substrate 200 of the solar cell 250. A corresponding N-type diffusion region 208 is disposed in the substrate 200. A P-type dopant-containing layer 204 is disposed on the region of N-type doped silicon nano-particles 202 and on the first surface 201 of the substrate 200 adjacent the region of N-type doped silicon nano-particles 202. A corresponding P-type diffusion region 210 is disposed in the substrate 200, adjacent the N-type diffusion region 208. An etch resistant layer 206 is disposed on the P-type dopant-containing layer 204. A first metal contact 212A is disposed through the etch resistant layer 206, the P-type dopant-containing layer 204 and the region of N-type doped silicon nano-particles 202, and to the N-type diffusion region 208. A second metal contact 212B is disposed through the etch resistant layer 206 and the P-type dopant-containing layer 204, and to the P-type diffusion region 210.

In an embodiment, the solar cell 250 further includes a texturized second surface 222 of the substrate 200, opposite the first surface 201. In one such embodiment, the first surface 201 of the substrate 200 is a back surface of the solar cell 250, and the second surface 222 of the substrate 200 is a light receiving surface of the solar cell 250. In an embodiment, the solar cell further includes an anti-reflective coating layer 230 disposed on the texturized second surface 222 of the substrate 200. In an embodiment, region of N-type doped silicon nano-particles 202 is composed of phosphorous-doped silicon nano-particles having an average particles size approximately in the range of 5-100 nanometers. In an embodiment, the P-type dopant-containing layer 204 is a layer of borosilicate glass (BSG). In an embodiment, the etch resistant layer 206 is a silicon nitride layer. In an embodiment, the substrate 200 is a single crystalline silicon substrate.

More generally, referring to FIGS. 1E and 2G, a porous layer silicon nano-particle layer may be retained on a substrate of a solar cell. Therefore, a solar cell structure may ultimately retain, or at least temporarily include, such a porous layer as a consequence of processing operations. In an embodiment, portions of a porous silicon nano-particle layer (e.g., 102 or 202) are not removed in process operations used to fabricate the solar cell, but rather remain as an artifact on the surface of a substrate, or on a layer or stack of layers above a global substrate, of the solar cell.

Overall, although certain materials are described specifically above, some materials may be readily substituted with others with other such embodiments remaining within the spirit and scope of embodiments of the present invention. For example, in an embodiment, a different material substrate, such as a group III-V material substrate, can be used instead of a silicon substrate. Furthermore, it is to be understood that, where N+ and P+ type doping is described specifically, other embodiments contemplated include the opposite conductivity type, e.g., P+ and N+ type doping, respectively.

Thus, methods of fabricating solar cell emitter regions using N-type doped silicon nano-particles and the resulting solar cells have been disclosed. In accordance with an embodiment of the present invention, a method of fabricating an emitter region of a solar cell includes forming a plurality of regions of N-type doped silicon nano-particles on a first surface of a substrate of the solar cell. A P-type dopant-containing layer is formed on the plurality of regions of N-type doped silicon nano-particles and on the first surface of the substrate between the regions of N-type doped silicon nano-particles. At least a portion of the P-type dopant-containing layer is mixed with at least a portion of each of the plurality of regions of N-type doped silicon nano-particles. In one embodiment, subsequent to mixing the P-type dopant-containing layer with the regions of N-type doped silicon nano-particles, diffusing N-type dopants from the regions of N-type doped silicon nano-particles and forming corresponding N-type diffusion regions in the substrate, and diffusing P-type dopants from the P-type dopant-containing layer and forming corresponding P-type diffusion regions in the substrate, between the N-type diffusion regions.

1. A method of fabricating an emitter region of a solar cell, the method comprising:
forming a plurality of regions of N-type doped silicon nano-particles on a first surface of a substrate of the solar cell;
forming a P-type dopant-containing layer on the plurality of regions of N-type doped silicon nano-particles and on the first surface of the substrate between the regions of N-type doped silicon nano-particles; and
mixing at least a portion of the P-type dopant-containing layer with at least a portion of each of the plurality of regions of N-type doped silicon nano-particles.

2. The method of claim 1, further comprising:
subsequent to mixing the P-type dopant-containing layer with the regions of N-type doped silicon nano-particles, diffusing N-type dopants from the regions of N-type doped silicon nano-particles and forming corresponding N-type diffusion regions in the substrate, and diffusing P-type dopants from the P-type dopant-containing layer and forming corresponding P-type diffusion regions in the substrate, between the N-type diffusion regions.

3. The method of claim 2, wherein diffusing N-type dopants from the regions of N-type doped silicon nano-particles further comprises diffusing an amount of P-type dopants from the doped silicon nano-particles mixed with the P-type dopant-containing layer, wherein the corresponding N-type diffusion regions comprise the amount of P-type dopants.

4. The method of claim 2, wherein the diffusing is performed in a same heating operation as the mixing.

5. The method of claim 2, wherein the first surface of the substrate is a back surface of the solar cell, the second surface of the substrate is a light receiving surface of the solar cell, the method further comprising:
forming metal contacts to the N-type and P-type diffusion regions.

6. The method of claim 1, wherein forming the plurality of regions of N-type doped silicon nano-particles comprises printing or spin-on coating phosphorous-doped silicon nano-particles having an average particles size approximately in the range of 5-100 nanometers and a porosity approximately in the range of 10-50%.

7. The method of claim 1, wherein forming the P-type dopant-containing layer comprises forming a layer of boron oxide (B₂O₃) on the plurality of regions of N-type doped silicon nano-particles and on the first surface of the substrate between the regions of N-type doped silicon nano-particles.

8. The method of claim 7, wherein the forming the layer of B₂O₃ comprises depositing boron tribromide (BBr₃) and oxygen (O₂).

9. The method of claim 1, wherein the N-type doped silicon nano-particles are phosphorus-doped silicon nano-particles, wherein the P-type dopant-containing layer is a boron-containing layer, and wherein mixing the P-type dopant-containing layer with the regions of N-type doped silicon nano-particles comprises forming corresponding regions of borophosphosilicate glass (BPSG).

10. The method of claim 1, wherein the mixing is performed at a temperature approximately in the range of 700-1100 degrees Celsius for a duration approximately in the range of 1-100 minutes.

11. A solar cell fabricated according to the method of claim 1.

12. A method of fabricating an emitter region of a solar cell, the method comprising:
forming a plurality of regions of N-type doped silicon nano-particles on a first surface of a substrate of the solar cell;
forming a P-type dopant-containing layer on the plurality of regions of N-type doped silicon nano-particles and on the first surface of the substrate between the regions of N-type doped silicon nano-particles;
forming an etch resistant layer on the P-type dopant-containing layer; and
etching a second surface of the substrate, opposite the first surface, to texturize the second surface of the substrate, wherein the etch resistant layer protects the P-type dopant-containing layer during the etching.

13. The method of claim 12, further comprising:
subsequent to forming the P-type dopant-containing layer, heating the substrate to diffuse N-type dopants from the regions of N-type doped silicon nano-particles and form corresponding N-type diffusion regions in the substrate, and to diffuse P-type dopants from the P-type dopant-containing layer and form corresponding P-type diffusion regions in the substrate, between the N-type diffusion regions.

14. The method of claim 13, wherein the heating is performed at a temperature approximately in the range of 850-1100 degrees Celsius for a duration approximately in the range of 1-100 minutes.

15. The method of claim 13, wherein the heating is performed subsequent to the etching.

16. The method of claim 13, wherein the first surface of the substrate is a back surface of the solar cell, the second surface of the substrate is a light receiving surface of the solar cell, the method further comprising:
forming metal contacts to the N-type and P-type diffusion regions.

17. The method of claim 12, further comprising:
subsequent to etching the second surface of the substrate, forming an anti-reflective coating layer on the texturized second surface of the substrate.

18. The method of claim 12, wherein forming the plurality of regions of N-type doped silicon nano-particles comprises printing or spin-on coating phosphorous-doped silicon nano-particles having an average particles size approximately in the range of 5-100 nanometers and a porosity approximately in the range of 10-50%.

19. The method of claim 12, wherein forming the P-type dopant-containing layer comprises forming a layer of borosilicate glass (BSG).

20. The method of claim 12, wherein forming the etch resistant layer comprises forming a silicon nitride layer.

21. The method of claim 12, wherein the substrate is a single crystalline silicon substrate, and wherein etching the second surface of the substrate comprises treating the second surface with a hydroxide-based wet etchant.

22. A solar cell fabricated according to the method of claim 12.

23.-30. (canceled)
